(19) United States
(12) Patent Application Publication
(10) Pub. No.: US 2025/0284075 A1
(43) Pub. Date: Sep. 11, 2025

(54) FLUIDIC-CHANNELS CONFIGURED AS PHOTONIC WAVEGUIDES FOR BOTH COMMUNICATION AND COOLING

(71) Applicant: Microsoft Technology Licensing, LLC, Redmond, WA (US)

(72) Inventors: Maria Leena Kyllikki VIITANIEMI, Seattle, WA (US); Vaidehi ORUGANTI, Kirkland, WA (US); Eric Clarence PETERSON, Woodinville, WA (US); Bharath RAMAKRISHNAN, Kirkland, WA (US); Teresa Ann NICK, Towson, MD (US); Husam Atallah ALISSA, Snoqualmie, WA (US); Winston Allen SAUNDERS, Seattle, WA (US); Nicholas A. KEEHN, Kirkland, WA (US)

(21) Appl. No.: 18/601,625

(22) Filed: Mar. 11, 2024

(51) Int. Cl. G02B 6/42; G02B 6/43

(52) U.S. Cl. CPC G02B 6/4268; G02B 6/43

(57) ABSTRACT

Systems and apparatus including fluidic-channels configured as photonic waveguides for both communication and for cooling are described. An example die comprises a first portion of the die including a first set of components formed within the first portion of the die. The die further includes a second portion of the die including a set of fluidic-channels formed within the second portion of the die, where the set of fluidic-channels provides both: (1) circulation of a fluid through at least the second portion of the die, and (2) communication between at least a subset of the first set of components formed within the first portion of the die and at least a subset of the second set of components formed within the second portion of the die. Such dies can also be combined to create three-dimensional integrated circuit (3DIC) systems, 2.5DIC systems, or systems with horizontal communication among the dies.

### BACKGROUND

As computing and communication systems become more complicated, communication within such systems is getting more complicated and more important. Latency and bandwidth requirements are also becoming more stringent. Such systems often include multiple dies arranged on top of each other or next to each other. Through-silicon vias (TSVs) have been used for allowing communication among such stacked dies. However, the high density of TSVs required for meeting the latency and bandwidth requirements is resulting in problems with cooling such systems.

Accordingly, there is a need for improved systems that can allow for both high-density communication among components and yet effectively manage cooling of the components.

### SUMMARY

In one example, the present disclosure relates to a die including a first portion of the die including a first set of components formed within the first portion of the die. The die may further include a second portion of the die including a set of fluidic-channels formed within the second portion of the die, wherein the set of fluidic-channels provides both: (1) circulation of a fluid through at least the second portion of the die, and (2) communication between at least a subset of the first set of components formed within the first portion of the die and at least a subset of the second set of components formed within the second portion of the die.

In another example, the present disclosure relates to a system comprising a first portion of the system including a first set of components formed within the first portion of the system, and (2) a second portion of the system including a first set of fluidic-channels formed within the second portion of the system. The system may further include a second die comprising: (1) a third portion of the system including a second set of components formed within the third portion of the system, and (2) a fourth portion of the system including a second set of fluidic-channels formed within the fourth portion of the system. Each of the first set of fluidic-channels and the second set of fluidic-channels may provide both: (1) circulation of a fluid through at least the second portion of the system or the fourth portion of the system and (2) communication between at least a subset of the first set of components formed within the first portion of the system and at least a subset of the second set of components formed within the third portion of the system.

In yet another example, the present disclosure relates to a three-dimensional integrated circuit (3DIC) system. The 3DIC system may include a bottom die comprising: (1) a first portion of the 3DIC-system including a first set of components formed within the first portion of the 3DIC-system, and (2) a second portion of the 3DIC-system including a first set of vertical fluidic-channels formed within the second portion of the 3DIC-system.

The 3DIC system may further include a top die, stacked on top of the bottom die, comprising: (1) a third portion of the 3DIC-system including a second set of components formed within the third portion of the 3DIC-system, and (2) a fourth portion of the 3DIC-system including a second set of vertical fluidic-channels formed within the fourth portion of the 3DIC-system. Each of the first set of vertical fluidic-channels and the second set of vertical fluidic-channels may provide both: (1) circulation of a fluid through at least the second portion of the 3DIC-system or the fourth portion of the 3DIC-system, and (2) communication between at least a subset of the first set of components formed within the first portion of the 3DIC-system and at least a subset of the second set of components formed within the third portion of the 3DIC-system.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

The present disclosure is illustrated by way of example and is not limited by the accompanying figures, in which like references indicate similar elements. Elements in the figures are illustrated for simplicity and clarity and have not necessarily been drawn to scale.

FIG. 1 shows a diagram of an example die with fluidic-channels configured as photonic waveguides within an inactive area of the die in accordance with one example;

FIG. 2 shows a diagram of a three-dimensional integrated circuit (3DIC)-system with two dies stacked on top of each other in accordance with one example;

FIG. 3 shows a diagram of the 3DIC-system of FIG. 2 arranged on top of a substrate;

FIG. 4 shows a diagram of a 2.5 dimension (2.5D) integrated circuit system with two dies arranged next to each other on an interposer in accordance with one example;

FIG. 5 shows a diagram of a system with communication among dies arranged on a substrate; and

FIG. 6 is a block diagram of a chassis with pipes for circulating a fluid for use with the fluidic-channels described with respect to FIGS. 1-5.

### DETAILED DESCRIPTION

Examples described in this disclosure relate to fluidic-channels configured as photonic waveguides for both communication and cooling of dies. As computing and communication systems become more complicated, communication within such systems is getting more complicated and more important. Latency and bandwidth requirements for such computing systems, including those formed on a motherboard, are also becoming more stringent. Such systems often include multiple dies arranged on top of each other or next to each other. As noted earlier, through-silicon vias (TSVs), or similar metal structures, have been used for allowing communication among such stacked dies. However, the high density of TSVs required for meeting the latency and bandwidth requirements is resulting in problems with cooling such systems.

Advantageously, the fluidic-channels described herein, acting as waveguides, allow for one structural element to perform both cooling and communication. One hurdle with bringing photonics onto the chip are the cooling requirements; the use of fluidic-channels addresses this problem with the cooling being close to the heat producing elements (e.g., a light source, such as a laser). Additionally, a constraint with the use of fluidic-channels is the need to retain structural integrity while forming channels. The proposed solutions described herein allow one to use the same structural elements for many purposes, and thereby reduce the need for fabricating competing elements, such as additional through-silicon vias in the same region of the die. Moreover, advantageously, the use of photonic waveguides allow for wavelength division multiplexing (e.g., sending multiple wavelengths through the same fluidic-channel). Therefore, one can increase the density of communication. This, in turn, can save both “beach front” I/O space on the chips and space within the chips.

Using photons, rather than electrons, allows for faster modulation and therefore higher bandwidth. Depending on the index of refraction of the liquid, the speed of the photons may be faster than the speed of electrons. Additionally, photons have less attenuation than electrons, allowing for further reach. These improvements can be implemented in the context of various types of 3D stacking arrangements, including face-to-back (F2B) stacking and back-to-back (B2B) stacking, 2.5D stacking arrangements, and even a non-stacking arrangement of dies that allow communication among dies in a horizontal plane.

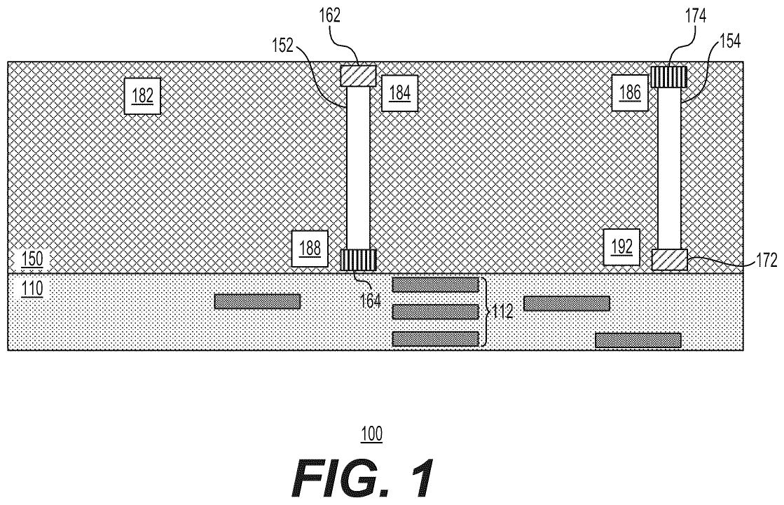

FIG. 1 shows a diagram of an example die 100 with fluidic-channels configured as photonic waveguides within an inactive area of the die in accordance with one example. Die 100 includes an active area 110 and an inactive area 150. In this example, active area 110 may include metal layers 112 and active circuitry, such as transistors, capacitors, diodes, resistors, and the like. Active area 110 may include active circuitry corresponding to one or both logic and memory. Processing logic may comprise one or more cores or other types of processing logic. Memory may comprise a memory array or several banks of memory arrays. The memory arrays may be implemented as static random access memory (SRAM) arrays. In addition, each SRAM may be implemented as a 2-port SRAM allowing for simultaneous read/write operations via buffers. Other memory technologies may also be used. As an example, dynamic random access memory (DRAM) or flash memory may be used.

With continued reference to FIG. 1, inactive area 150 may include fluidic-channels configured as photonic waveguides. As an example, inactive area 150 is shown as including a vertical fluidic-channel 152 and another vertical fluidic-channel 154. Vertical fluidic-channel 152 is coupled to a light source 162 on one end and a photodetector 164 on the other end. Vertical fluidic-channel 154 is coupled to a light source 172 on one end and a photodetector 174 on the other end. Light source 162 and 172 may be a small photonic chip that includes a laser source, modulators (e.g., for transmitting the optical signal), and photonic rings (e.g., for selecting different wavelengths).

A coating or a window that is transparent to the visible light (or some other electromagnetic radiation) can be used to ensure that the light source and the photodetector do not interact with the fluid. Inactive area 150 may further include additional fluidic-channels, including horizontal fluidic-channels 182, 184, 186, 188, and 192. In addition, although not shown in FIG. 1, inactive area 150 may include diagonal channels or channels that are arranged in another manner. Moreover, although not shown in FIG. 1, inactive area 150 may include other optical components, such as optical encoders, decoders, Mach-Zhander interferometers, ring modulators, waveguide couplers, or other types of electro-optical components.

Still referring to FIG. 1, in terms of the operation of the fluidic-channels, each of these fluidic-channels may comprise a fluid that is transparent to visible light or another type of electromagnetic radiation that is being used for communication via these channels. Any fluid that is transparent for the desired wavelength could be used. Fluids having low chromatic dispersion may be preferred in certain implementations if multiplexing of optical signals is being performed. By temperature stabilizing the laser sources and the elements (e.g., ring resonators) used for selecting wavelengths, one can increase the density of wavelength multiplexing.

To ensure the operation of the fluidic-channels as waveguides, the fluid should have a higher index of refraction than the surrounding media. To ensure this outcome, the inner surface of fluidic-channels may be coated with appropriate coatings. The index of refraction of the selected fluid will also determine the speed of the radiation within the media. Example fluids for use with the fluidic-channels described herein include deionized water or a combination of polyethylene glycol and deionized water (e.g., 25 percent polyethylene glycol and 75 percent water). The fluid flowing through the fluidic-channels allows cooling of the components within die 100.

In terms of formation of the fluidic-channels as part of die 100, during wafer level processing, holes can be drilled in the inactive area of the die. The process of drilling these holes is similar to the process of drilling holes for embedded cooling or for through-silicon vias. After the drilling of the holes, if necessary, materials having the desirable index of refraction can be sprayed, or otherwise formed, to coat the inside walls of the holes. The fluidic-channels may also be pre-formed using a polymer material (or another appropriate material) and then inserted into the drilled holes. Additional processing can be performed to create space for embedding other optical components, such as optical encoders, decoders, Mach-Zhander interferometers, ring modulators, waveguide couplers, or other types of electro-optical components. Pick-and-place tools can be used to arrange (or embed) the optical components in the appropriate areas of the wafer. Subsequently, the wafer can be diced to form separate dies (e.g., die 100).

In certain examples, die 100 can also be formed by bonding, or otherwise connecting, two different types of wafers. One of the wafers can include the fluidic-channels and optical components, such as optical encoders, decoders, Mach-Zhander interferometers, ring modulators, waveguide couplers, or other types of electro-optical components. The other wafer can include active circuitry and metal layers, and the two wafers can be bonded together. Subsequently, the bonded wafers can be diced to form separate dies (e.g., die 100). Alternatively, wafer-on-die fabrication techniques can also be used to form die 100. Although FIG. 1 shows die 100 as having a certain number of components arranged in a certain manner, die 100 may include additional or fewer components arranged differently.

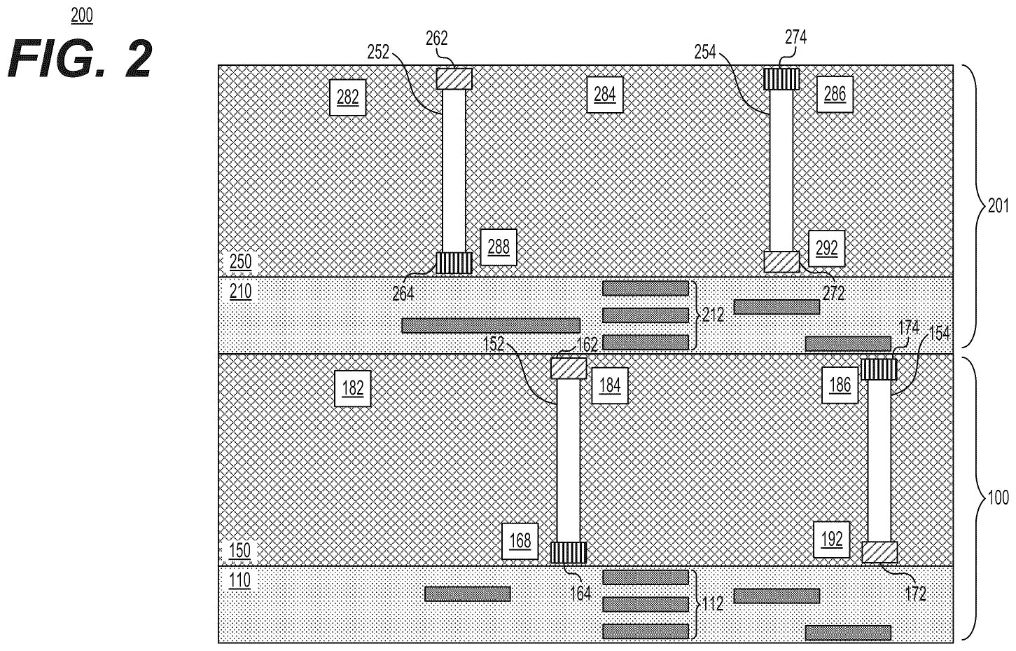

FIG. 2 shows a diagram of a three-dimensional integrated circuit (3DIC)-system 200 with two dies stacked on top of each other in accordance with one example. In this example, 3DIC-system 200 comprises two dies (die 100 and die 201) that are coupled to each other. Unless indicated otherwise, the same or similar areas, layers, and components that are shown in FIG. 2 are referred to using the same reference numbers as used in the previous figure (e.g., FIG. 1). Similar to die 100 of FIG. 1, die 201 includes an active area 210 and an inactive area 250. In this example, active area 210 may include metal layers 212 and active circuitry, such as transistors, capacitors, diodes, resistors, and the like. Active area 210 may include active circuitry corresponding to one or both logic and memory. Processing logic may comprise one or more cores or other types of processing logic. Memory may comprise a memory array or several banks of memory arrays. The memory arrays may be implemented as static random access memory (SRAM) arrays. In addition, each SRAM may be implemented as a 2-port SRAM allowing for simultaneous read/write operations via buffers. Other memory technologies may also be used. As an example, dynamic random access memory (DRAM) or flash memory may be used.

With continued reference to FIG. 2, inactive area 250 may include fluidic-channels configured as photonic waveguides. As an example, inactive area 250 is shown as including a vertical fluidic-channel 252 and another vertical fluidic-channel 254. Vertical fluidic-channel 252 is coupled to a light source 262 on one end and a photodetector 264 on the other end. Vertical fluidic-channel 254 is coupled to a light source 272 on one end and a photodetector 274 on the other end. Light source 262 and 272 may be a small photonic chip that includes a laser source, modulators (e.g., for transmitting the optical signal), and photonic rings (e.g., for selecting different wavelengths).

As explained before with respect to die 100 of FIG. 1, a coating or a window that is transparent to the visible light (or some other electromagnetic radiation) can be used to ensure that the light source and the photodetector do not interact with the fluid. Inactive area 250 may further include additional fluidic-channels, including horizontal fluidic-channels 282, 284, 286, 288, and 292. In addition, although not shown in FIG. 2, inactive area 250 may include diagonal channels or channels that are arranged in another manner. Moreover, although not shown in FIG. 2, inactive area 250 may include other optical components, such as optical encoders, decoders, Mach-Zhander interferometers, ring modulators, waveguide-couplers, or other types of electro-optical components.

Still referring to FIG. 2, in terms of the operation of the fluidic-channels, each of these fluidic-channels may comprise a fluid that is transparent to visible light or another type of electromagnetic radiation that is being used for communication via these channels. Any fluid that is transparent for the desired wavelength could be used. Fluids having low chromatic dispersion may be preferred in certain implementations if multiplexing of optical signals is being performed. In addition, as noted earlier, by temperature stabilizing the laser sources and the elements (e.g., ring resonators) used for selecting wavelengths, one can increase the density of wavelength multiplexing.

To ensure the operation of the fluidic-channels as waveguides, the fluid should have a higher index of refraction than the surrounding media. To ensure this outcome, the inner surface of fluidic-channels may be coated with appropriate coatings. The index of refraction of the selected fluid will also determine the speed of the radiation within the media. Example fluids for use with the fluidic-channels described herein include deionized water or a combination of polyethylene glycol and deionized water (e.g., 25 percent polyethylene glycol and 75 percent water). The fluid flowing through the fluidic-channels allows cooling of the components within die 201.

Fluidic-channels and other optical components shown as part of die 201 may be formed using similar techniques as described earlier with respect to die 100 of FIG. 1. Although FIG. 2 shows a certain number of components of 3DIC-system 200 arranged in a certain manner, there could be more or fewer number of components arranged differently. As an example, the 3DIC-system 200 may include more than two dies.

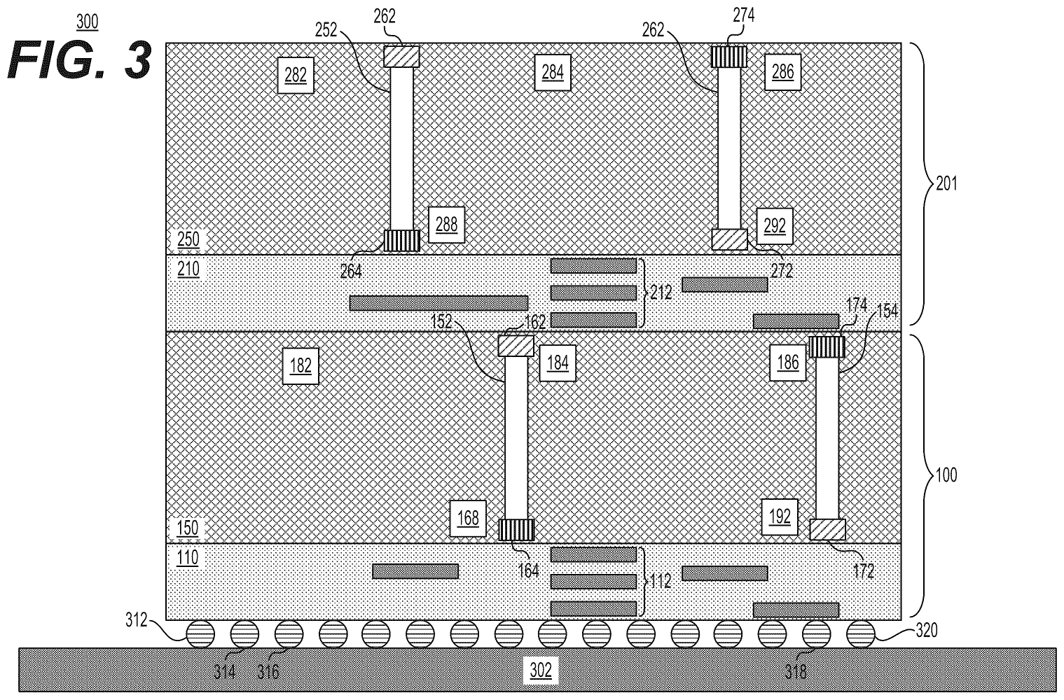

FIG. 3 shows a diagram of the 3DIC-system 200 of FIG. 2 arranged on top of a substrate 302. Unless indicated otherwise, the same or similar areas, layers, and components that are shown in FIG. 2 are referred to using the same reference numbers as used in the previous figure (e.g., FIG. 1). 3DIC-system 200 is shown coupled to substrate 302 using bumps 312, 413, 316, 318, and 320. Bumps 312, 314, 316, 318, and 320 can be used to couple power, ground, and other signals to die 100, which is further coupled with die 201. In addition, although not shown in FIG. 3, substrate 302 may include fluidic-channels and optical components, as well.

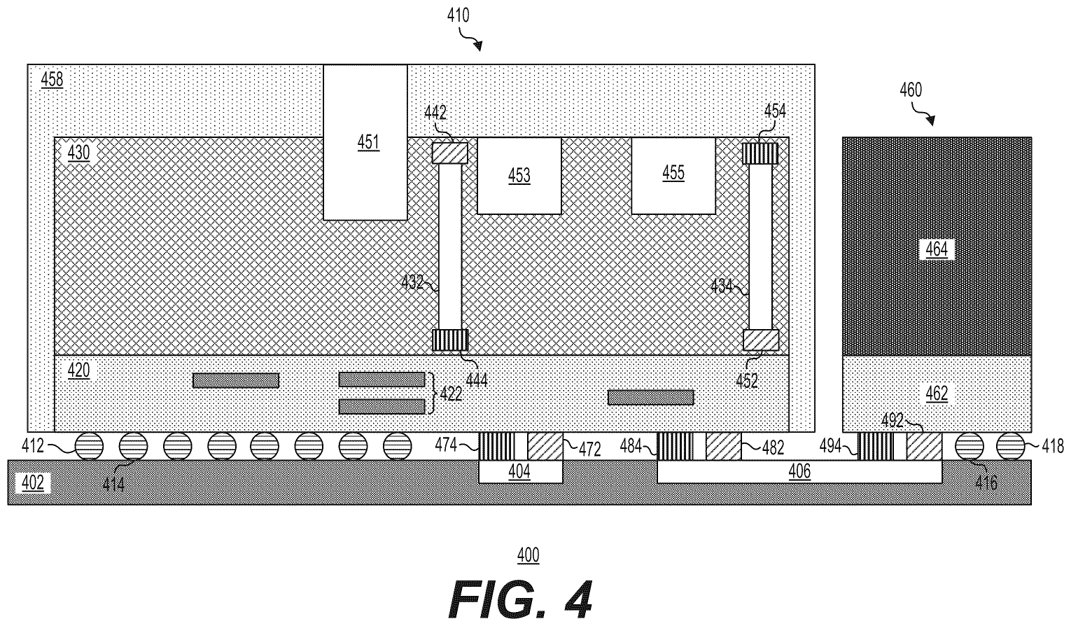

FIG. 4 shows a diagram of a system 400 with two dies arranged next to each other on an interposer in accordance with one example. System 400 includes die 410 coupled to another die 460 via an interposer 402. Interposer 402 may be configured as a printed circuit board or a similar support structure for mounting dies or other types of components. Die 410 includes an active area 420 and an inactive area 430. In this example, active area 420 may include metal layers 422 and active circuitry, such as transistors, capacitors, diodes, resistors, and the like. Active area 420 may include active circuitry corresponding to one or both logic and memory. Processing logic may comprise one or more cores or other types of processing logic. Memory may comprise a memory array or several banks of memory arrays. The memory arrays may be implemented as static random access memory (SRAM) arrays. In addition, each SRAM may be implemented as a 2-port SRAM allowing for simultaneous read/write operations via buffers. Other memory technologies may also be used. As an example, dynamic random access memory (DRAM) or flash memory may be used.

With continued reference to FIG. 4, inactive area 430 of die 410 may include fluidic-channels configured as photonic waveguides. As an example, inactive area 430 is shown as having a vertical fluidic-channel 432 and another vertical fluidic-channel 434. Vertical fluidic-channel 432 is coupled to a light source 442 on one end and a photodetector 444 on the other end. Vertical fluidic-channel 434 is coupled to a light source 452 on one end and a photodetector 454 on the other end. As explained before with respect to die 100 of FIG. 1, a coating or a window that is transparent to the visible light (or some other electromagnetic radiation) can be used to ensure that the light source and the photodetector do not interact with the fluid. Inactive area 430 may further include additional fluidic-channels, including horizontal fluidic-channels 451, 453, and 455. In addition, although not shown in FIG. 4, inactive area 430 may include diagonal channels or channels that are arranged in another manner. Moreover, although not shown in FIG. 4, inactive area 430 may include other optical components, such as optical encoders, decoders, Mach-Zhander interferometers, ring modulators, waveguide couplers, or other types of electro-optical components. Die 410 is further shown as encapsulated on its three sides by epoxy 458.

Still referring to FIG. 4, in terms of the operation of the fluidic-channels, as described earlier, each of these fluidic-channels may comprise a fluid that is transparent to visible light or another type of electromagnetic radiation that is being used for communication via these channels. Any fluid that is transparent for the desired wavelength could be used. Fluids having low chromatic dispersion may be preferred in certain implementations if multiplexing of optical signals is being performed. To ensure the operation of the fluidic-channels as waveguides, the fluid should have a higher index of refraction than the surrounding media. To ensure this outcome, the inner surface of fluidic-channels may be coated with appropriate coatings. The index of refraction of the selected fluid will also determine the speed of the radiation within the media. Example fluids for use with the fluidic-channels described herein include deionized water or a combination of polyethylene glycol and deionized water (e.g., 25 percent polyethylene glycol and 75 percent water). The fluid flowing through the fluidic-channels allows cooling of the components within die 401. Fluidic-channels and other optical components shown as part of die 410 may be formed using similar techniques as described earlier with respect to die 100 of FIG. 1.

With continued reference to FIG. 4, die 460 includes an active area 462 and an inactive area 464. No fluidic-channels are shown as part of die 460. Instead of such channels, inactive area 464 of die 460 may include through-silicon vias (TSVs) or other such structures. Bumps 412 and 414 can be used to couple a subset of the power, ground, and other signals to die 410 and substrate 402. Similarly, bumps 416 and 418 can be used to couple a subset of the power, ground, and other signals to die 460 and substrate 402. Die 410 is further coupled via a light source 472 and a photodetector 474 to a fluidic-channel 404 formed within substrate 402. In addition, die 410 is further coupled via another light source 482 and a photodetector 484 to a fluidic-channel 406 formed within substrate 402. The other end of fluidic-channel 406 is shown as coupled to die 460 via a light source 492 and a photodetector 494. Although not shown in FIG. 4, substrate 402 may include additional optical components, such as optical encoders, decoders, Mach-Zhander interferometers, ring modulators, waveguide couplers, or other types of electro-optical components. These components may be used to interconnect die 410 with die 460 through interposer 402. Although FIG. 4 shows a certain number of components of system 400 arranged in a certain manner, there could be more or fewer number of components arranged differently. As an example, additional die may be stacked on each of die 410 and die 460, respectively. Similarly, although FIG. 4 shows an interposer for interconnecting the two dies, other interconnection arrangements may also be used. Underfill may be used to seal fluidic-channels and control the co-efficient of thermal expansion mismatches between the dies (e.g., die 410 and die 460) and the substrate 402.

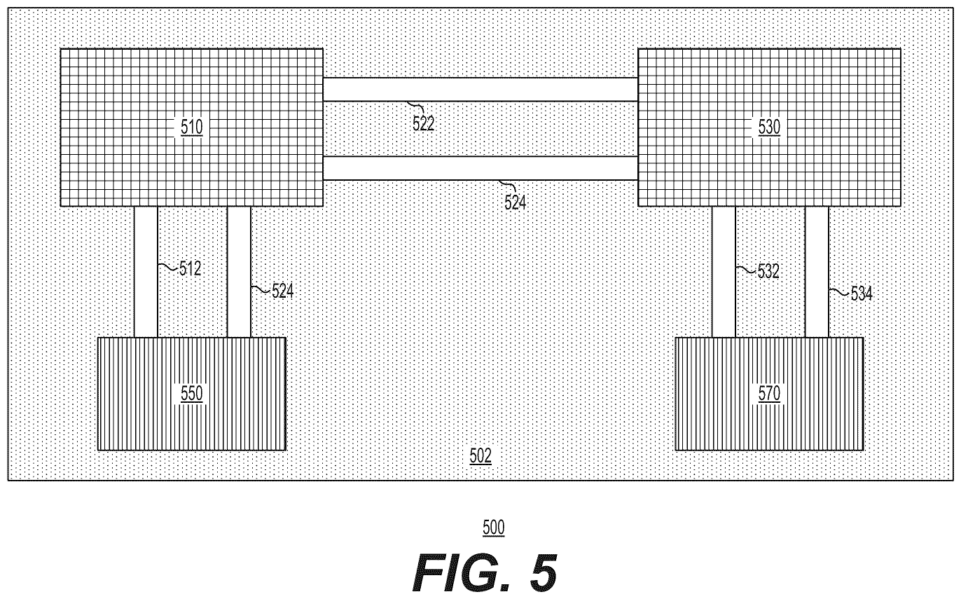

FIG. 5 shows diagram of a system 500 with communication among dies arranged on a substrate 502. System 500 shows communication between dies 510 and 550, which are coupled via horizontal fluidic-channels 512 and 514. In this example, die 510 may correspond to processing logic included in a CPU or a GPU and die 550 may correspond to memory. System 500 further shows communication between dies 530 and 570, which are coupled via horizontal fluidic-channels 532 and 534. In this example, die 530 may correspond to processing logic included in a CPU or a GPU and die 570 may correspond to memory. System 500 further shows communication between dies 510 and 530, which are coupled via horizontal fluidic-channels 522 and 524. Each of the horizontal fluidic-channels may be formed within substrate 502 and may be further coupled to fluidic-channels formed within at least dies 510 and 530.

Horizontal fluidic-channels 512, 524, 522, 524, 532, and 534 may be formed by drilling holes, or otherwise removing material, into substrate 502. Additional fabrication may be performed similar to as described earlier with respect to FIGS. 1-4. Operationally, horizontal fluidic-channels 512, 524, 522, 524, 532, and 534 may carry fluid that is circulated to provide cooling to substrate 502. Similarly, fluid flowing through horizontal fluidic-channels 512, 524, 522, 524, 532, and 534 can flow through vertical fluidic-channels formed within respective dies. Although FIG. 5 shows a certain number of components of system 500 arranged in a certain manner, there could be more or fewer number of components arranged differently. As an example, additional die may be stacked on each of dies 510, 530, 550, and 570, respectively. Similarly, although FIG. 5 shows a substrate 502 for interconnecting the dies to allow for both cooling and communication among the dies, other interconnection arrangements may also be used.

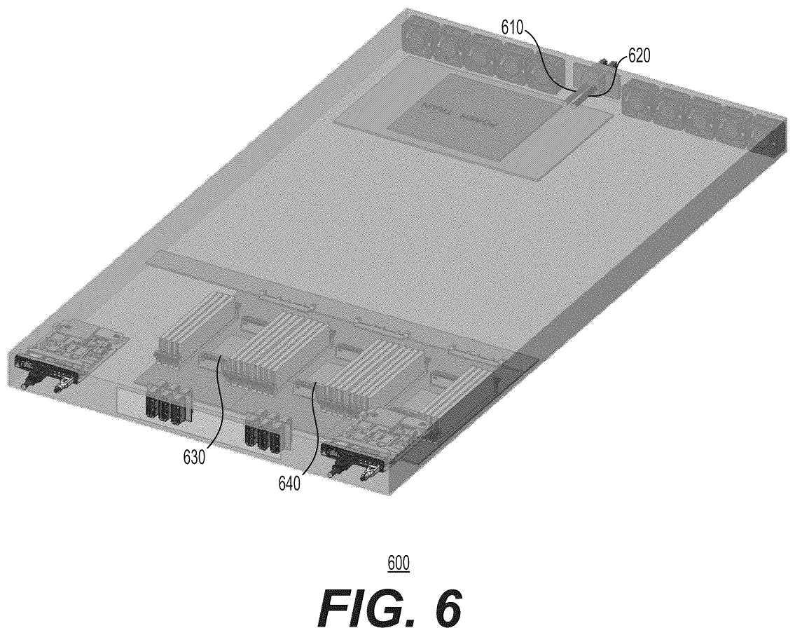

FIG. 6 is a block diagram of a chassis 600 with pipes for circulating a fluid for use with the fluidic-channels described with respect to FIGS. 1-5. As shown in FIG. 6, fluid can be delivered to a fluidics package (e.g., micro-fluidics packages 630 and 640), which can be mounted on top of the packaged die(s), 3DIC-systems, or 2.5DIC-systems being cooled. Cooled fluid can be circulated via pipes (e.g., pipe 610 and additional attached pipes (not shown)), or similar structures, for circulation to the fluidics package mounted on top of the system being cooled. Heated fluid (post-circulation) can be circulated via pipes (e.g., pipe 620 and additional attached pipes (not shown)) to a heat exchanger. This way cooled fluid can be continuously piped to the fluidic-channels described earlier, allowing for both cooling of the components (e.g., dies, interposers, substrates, and other components formed within such structures) and photonic communication within the dies or among the dies, as explained earlier with respect to FIGS. 1-5. Although FIG. 6 shows a certain number of components of chassis 600 arranged in a certain manner, there could be more or fewer number of components arranged differently.

In conclusion, the present disclosure relates to [a die including a first portion of the die including a first set of components formed within the first portion of the die. The die may further include a second portion of the die including a set of fluidic-channels formed within the second portion of the die, wherein the set of fluidic-channels provides both: (1) circulation of a fluid through at least the second portion of the die, and (2) communication between at least a subset of the first set of components formed within the first portion of the die and at least a subset of the second set of components formed within the second portion of the die.

A first fluidic-channel from among the set of fluidic-channels may comprise a first photonic waveguide having a light source at a first end and a photodetector at a second end, opposite to the first end. A second fluidic-channel from among the set of fluidic-channels may comprise a second photonic waveguide having a photodetector at a third end and a light source at a fourth end, opposite to the third end. The first photonic waveguide may be configured to propagate optical signals from the first end to the second end and the second photonic waveguide may be configured to propagate optical signals from the fourth end to the third end.

A first subset of the set of fluidic-channels may comprise vertical fluidic-channels and a second subset of the set of fluidic-channels may comprise horizontal fluidic-channels. The die may further comprise optical components formed within the second portion of the die. The optical components may include one or more of optical encoders, decoders, Mach-Zhander interferometers, ring modulators, waveguide couplers, or other types of electro-optical components.

The fluid may comprise de-ionized water or a combination of polyethylene glycol and the de-ionized water. The fluid may be selected to have a higher index of refraction relative to a surrounding medium.

In another example, the present disclosure relates to a system comprising a first portion of the system including a first set of components formed within the first portion of the system, and (2) a second portion of the system including a first set of fluidic-channels formed within the second portion of the system. The system may further include a second die comprising: (1) a third portion of the system including a second set of components formed within the third portion of the system, and (2) a fourth portion of the system including a second set of fluidic-channels formed within the fourth portion of the system. Each of the first set of fluidic-channels and the second set of fluidic-channels may provide both: (1) circulation of a fluid through at least the second portion of the system or the fourth portion of the system and (2) communication between at least a subset of the first set of components formed within the first portion of the system and at least a subset of the second set of components formed within the third portion of the system.

A first fluidic-channel from among the set of fluidic-channels may comprise a first photonic waveguide having a light source at a first end and a photodetector at a second end, opposite to the first end. A second fluidic-channel from among the second set of fluidic-channels may comprise a photonic waveguide having a photodetector at a first end and a light source at a second end, opposite to the first end.

The first die may be arranged on top of a circuit board comprising a third set of fluidic-channels allowing for optical communication between: (1) the first die and the second die, or (2) between the first die or the second die and other components external to the system. A first subset of the first set of fluidic-channels and the second set of fluidic-channels may comprise vertical fluidic-channels and a second subset of the first set of fluidic-channels and the second set of fluidic channels may comprise horizontal fluidic-channels.

The fluid may be selected to have a higher index of refraction relative to a surrounding medium. Examples of fluid include de-ionized water or a combination of polyethylene glycol and the de-ionized water. The system may further include optical components formed within the second portion of the first die and the fourth portion of the second die. The optical components may include one or more of optical encoders, decoders, Mach-Zhander interferometers, ring modulators, waveguide couplers, or other types of electro-optical components.

In yet another example, the present disclosure relates to a three-dimensional integrated circuit (3DIC) system. The 3DIC system may include a bottom die comprising: (1) a first portion of the 3DIC-system including a first set of components formed within the first portion of the 3DIC-system, and (2) a second portion of the 3DIC-system including a first set of vertical fluidic-channels formed within the second portion of the 3DIC-system.

The 3DIC system may further include a top die, stacked on top of the bottom die, comprising: (1) a third portion of the 3DIC-system including a second set of components formed within the third portion of the 3DIC-system, and (2) a fourth portion of the 3DIC-system including a second set of vertical fluidic-channels formed within the fourth portion of the 3DIC-system. Each of the first set of vertical fluidic-channels and the second set of vertical fluidic-channels may provide both: (1) circulation of a fluid through at least the second portion of the 3DIC-system or the fourth portion of the 3DIC-system, and (2) communication between at least a subset of the first set of components formed within the first portion of the 3DIC-system and at least a subset of the second set of components formed within the third portion of the 3DIC-system.

A first vertical fluidic-channel from among the first set of fluidic-channels may comprise a photonic waveguide having a light source at a first end and a photodetector at a second end, opposite to the first end. A second vertical fluidic-channel from among the second set of fluidic-channels may comprise a photonic waveguide having a photodetector at a first end and a light source at a second end, opposite to the first end. The bottom die may be arranged on top of a circuit board comprising a third set of fluidic-channels allowing for optical communication with other systems.

The fluid may be selected to have a higher index of refraction relative to a surrounding medium. Examples of fluid include de-ionized water or a combination of polyethylene glycol and the de-ionized water. The 3DIC-system may further include optical components formed within the second portion of the first die and the fourth portion of the second die. The optical components may include one or more of optical encoders, decoders, Mach-Zhander interferometers, ring modulators, waveguide couplers, or other types of electro-optical components.

It is to be understood that the methods, modules, and components depicted herein are merely exemplary. Alternatively, or in addition, the functionality described herein can be performed, at least in part, by one or more hardware logic components. For example, and without limitation, illustrative types of hardware logic components that can be used include Field-Programmable Gate Arrays (FPGAs), Application-Specific Integrated Circuits (ASICs), Application-Specific Standard Products (ASSPs), System-on-a-Chip systems (SOCs), Complex Programmable Logic Devices (CPLDs). In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or inter-medial components. Likewise, any two components so associated can also be viewed as being “operably connected,” or “coupled,” to each other to achieve the desired functionality.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the disclosure provides specific examples, various modifications and changes can be made without departing from the scope of the disclosure as set forth in the claims below. Accordingly, the specification and figures are to be regarded in an illustrative rather than a restrictive sense, and all such modifications are intended to be included within the scope of the present disclosure. Any benefits, advantages, or solutions to problems that are described herein with regard to a specific example are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A die comprising:
a first portion of the die including a first set of components formed within the first portion of the die; and
a second portion of the die including a set of fluidic-channels formed within the second portion of the die, wherein the set of fluidic-channels provides both: (1) circulation of a fluid through at least the second portion of the die, and (2) communication between at least a subset of the first set of components formed within the first portion of the die and at least a subset of the second set of components formed within the second portion of the die.

2. The die of claim 1, wherein a first fluidic-channel from among the set of fluidic-channels comprises a first photonic waveguide having a light source at a first end and a photodetector at a second end, opposite to the first end.

3. The die of claim 2, wherein a second fluidic-channel from among the set of fluidic-channels comprises a second photonic waveguide having a photodetector at a third end and a light source at a fourth end, opposite to the third end, and wherein the first photonic waveguide is configured to propagate optical signals from the first end to the second end and the second photonic waveguide is configured to propagate optical signals from the fourth end to the third end.

4. The die of claim 1, wherein a first subset of the set of fluidic-channels comprises vertical fluidic-channels and a second subset of the set of fluidic-channels comprises horizontal fluidic-channels.

5. The die of claim 1, wherein the fluid comprises de-ionized water or a combination of polyethylene glycol and the de-ionized water.

6. The die of claim 1, wherein the fluid is selected to have a higher index of refraction relative to a surrounding medium.

7. The die of claim 1, further comprising optical components formed within the second portion of the die, and wherein the optical components include one or more of optical encoders, decoders, Mach-Zhander interferometers, ring modulators, waveguide couplers, or other types of electro-optical components.

8. A system comprising:
a first portion of the system including a first set of components formed within the first portion of the system, and (2) a second portion of the system including a first set of fluidic-channels formed within the second portion of the system; and
a second die comprising: (1) a third portion of the system including a second set of components formed within the third portion of the system, and (2) a fourth portion of the system including a second set of fluidic-channels formed within the fourth portion of the system, wherein each of the first set of fluidic-channels and the second set of fluidic-channels provide both: (1) circulation of a fluid through at least the second portion of the system or the fourth portion of the system and (2) communication between at least a subset of the first set of components formed within the first portion of the system and at least a subset of the second set of components formed within the third portion of the system.

9. The system of claim 8, wherein a first fluidic-channel from among the first set of fluidic-channels comprises a photonic waveguide having a light source at a first end and a photodetector at a second end, opposite to the first end.

10. The system of claim 8, wherein a second fluidic-channel from among the second set of fluidic-channels comprises a photonic waveguide having a photodetector at a first end and a light source at a second end, opposite to the first end.

11. The system of claim 8, wherein the first die is arranged on top of a circuit board comprising a third set of fluidic-channels allowing for optical communication between: (1) the first die and the second die, or (2) between the first die or the second die and other components external to the system.

12. The system of claim 8, wherein a first subset of the first set of fluidic-channels and the second set of fluidic-channels comprises vertical fluidic-channels and a second subset of the first set of fluidic-channels and the second set of fluidic channels comprises horizontal fluidic-channels.

13. The system of claim 8, wherein the fluid is selected to have a higher index of refraction relative to a surrounding medium.

14. The system of claim 8, further comprising optical components formed within the second portion of the first die and the fourth portion of the second die, and wherein the optical components include one or more of optical encoders, decoders, Mach-Zhander interferometers, ring modulators, waveguide couplers, or other types of electro-optical components.

15. A three-dimensional integrated circuit (3DIC)-system comprising:
a bottom die comprising: (1) a first portion of the 3DIC-system including a first set of components formed within the first portion of the 3DIC-system, and (2) a second portion of the 3DIC-system including a first set of vertical fluidic-channels formed within the second portion of the 3DIC-system; and
a top die, stacked on top of the bottom die, comprising: (1) a third portion of the 3DIC-system including a second set of components formed within the third portion of the 3DIC-system, and (2) a fourth portion of the 3DIC-system including a second set of vertical fluidic-channels formed within the fourth portion of the 3DIC-system, wherein each of the first set of vertical fluidic-channels and the second set of vertical fluidic-channels provide both: (1) circulation of a fluid through at least the second portion of the 3DIC-system or the fourth portion of the 3DIC-system, and (2) communication between at least a subset of the first set of components formed within the first portion of the 3DIC-system and at least a subset of the second set of components formed within the third portion of the 3DIC-system.

16. The 3DIC-system of claim 15, wherein a first vertical fluidic-channel from among the first set of fluidic-channels comprises a photonic waveguide having a light source at a first end and a photodetector at a second end, opposite to the first end.

17. The 3DIC-system of claim 15, wherein a second vertical fluidic-channel from among the second set of fluidic-channels comprises a photonic waveguide having a photodetector at a first end and a light source at a second end, opposite to the first end.

18. The 3DIC-system of claim 15, wherein the bottom die is arranged on top of a circuit board comprising a third set of fluidic-channels allowing for optical communication with other systems.

19. The 3DIC-system of claim 15, wherein the fluid is selected to have a higher index of refraction relative to a surrounding medium.

20. The 3DIC-system of claim 15, further comprising optical components formed within the second portion of the first die and the fourth portion of the second die, and wherein the optical components include one or more of optical encoders, decoders, Mach-Zhander interferometers, ring modulators, waveguide couplers, or other types of electro-optical components.
